(19) United States
(12) Patent Application Publication
(10) Pub. No.: US 2007/0034922 A1
(43) Pub. Date: Feb. 15, 2007

(54) Integrated surround gate multifunctional memory device

(75) Inventor: Arup Bhattacharyya, Essex Junction, VT (US)

Correspondence Address: LEFFERT JAY & POLGLAZE, P.A.;Attn: Kenneth W. Bolvin, P. O. Box 581009, Minneapolis, MN, 55402, US

(73) Assignee: Micron Technology, Inc.

(21) Appl. No.: 11/202,282

(22) Filed: Aug. 11, 2005

(51) Int. Cl. H01L 29/94

(52) U.S. Cl. 257/296

(57) ABSTRACT

Vertical surround gate memory cells are formed around pillars on a substrate. Each memory cell is comprised of a gate stack formed around each pillar and a gate formed around each gate stack. The substrate can have multiple integrated memory types by varying the effective oxide thickness of the tunnel insulator of each gate stack and/or customizing the materials used in the gate stack for each type of desired memory on the substrate.

### TECHNICAL FIELD OF THE INVENTION

The present invention relates generally to memory devices and in particular the present invention relates to surround gate-based memory devices.

### BACKGROUND OF THE INVENTION

Memory devices are typically provided as internal, semiconductor, integrated circuits in computers or other electronic devices. There are many different types of memory including random-access memory (RAM), read only memory (ROM), non-volatile, floating gate NOR/NAND flash memory, and dynamic random access memory (DRAM).

Flash memories may use floating gate technology or trapping technology. Floating gate cells include source and drain regions that are laterally spaced apart to form an intermediate channel region. The source and drain regions are formed in a common horizontal plane of a silicon substrate. The floating gate, typically made of doped polysilicon, is disposed over the channel region and is electrically isolated from the other cell elements by oxide. The non-volatile memory function for the floating gate technology is created by the absence or presence of charge stored on the isolated floating gate.

The trapping technology functions as a non-volatile memory and can be implemented in a silicon-oxide-nitride-oxide-silicon (SONOS) architecture. The nitride trap layer can capture and store electrons or holes in order to act as a non-volatile memory.

Conventional DRAM cells are comprised of a switching transistor and an integrated storage capacitor tied to the storage node of the transistor. Charge storage is enhanced by providing appropriate storage capacity in the form of a stacked capacitor or a trench capacitor in parallel with the depletion capacitance of the floating storage node. DRAM cells are volatile and therefore lose data when the power is removed.

DRAMs use one or more arrays of memory cells arranged in rows and columns. Each of the rows of memory cells is activated by a corresponding row line that is selected from a row address. A pair of complementary digit lines are provided for each column of the array and a sense amplifier coupled to the digit lines for each column is enabled responsive to a respective column address. The sense amplifier senses a small voltage differential between the digit lines and amplifies such voltage differential.

Due to finite charge leakage across the depletion layer, the capacitor has to be recharged frequently to ensure data integrity. This is referred to in the art as refreshing and can be accomplished by periodically coupling the memory cells in the row to one of the digit lines after enabling the sense amplifiers. The sense amplifiers then restore the voltage level on the memory cell capacitor to a voltage level corresponding to the stored data bit. The permissible time between refresh cycles without losing data depends on various factors, such as rate of charge dissipation in the memory capacitor, but is typically in the range of milliseconds.

Computers, cell phones, and many other hand-held electronic devices employ several types of the above memories for working memory and data store. These memories require custom technologies that are typically not compatible to each other due to different cell design, fabrication techniques, and material characteristics. Consequently, the different memories are produced on different silicon substrates to minimize cost and maximize product yield.

Both DRAM and floating gate flash consume relatively high power compared to other memory technologies. DRAM requires frequent refreshing to maintain the data integrity while flash memory requires on-chip high voltage/current for programming and erase operations.

Another problem with these technologies is scalability. The DRAM has capacitor scalability problems while the flash has voltage and coupling noise scalability problems. Additionally, with progressive scaling of feature size, fundamental device leakage issues such as short-channel effects and gate dielectric leakage will need to be contained in order to take advantage of scaling.

For the reasons stated above, and for other reasons stated below which will become apparent to those skilled in the art upon reading and understanding the present specification, there is a need in the art for a low power, scalable, multifunctional memory cell.

### SUMMARY

The above-mentioned problems with DRAM and flash technologies and other problems are addressed by the present invention and will be understood by reading and studying the following specification.

The present invention encompasses an integrated, multifunctional memory cell that uses surround gate technology to provide multiple memory functions on a single substrate. The memory comprises a pillar fabricated in a substrate. A gate stack substantially surrounds the pillar. The gate stack is comprised of a tunnel insulator, a charge trap layer, and a charge blocking layer. A charge retention property of the device is adjusted during fabrication in response to an effective oxide thickness of the tunnel insulator. A gate substantially surrounds the gate stack.

Further embodiments of the invention include methods and apparatus of varying scope.

### BRIEF DESCRIPTION OF THE DRAWINGS

FIG. 1 shows a cross-sectional view of one embodiment of a surround gate transistor PROM/NROM/flash memory cell of the present invention.

FIG. 2 shows a cross-sectional view of one embodiment of a surround gate transistor DRAM cell of the present invention.

FIG. 3 shows a cross-sectional view of the embodiment of FIG. 1 along the x-x′ axis.

FIG. 4 shows a cross-sectional view of the embodiment of FIG. 2 along the y-y′ axis.

FIG. 5 shows a perspective view of an alternate embodiment of the surround gate transistor NVM/DRAM cell of the present invention.

FIG. 6 shows a cross-sectional view of the embodiment of FIG. 5.

FIG. 7 shows a top layout view of one embodiment of a memory array of the present invention.

FIG. 8 shows a block diagram of one embodiment of a chip architecture of a memory subsystem of the present invention.

### DETAILED DESCRIPTION

In the following detailed description of the invention, reference is made to the accompanying drawings that form a part hereof and in which is shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention. The following detailed description is, therefore, not to be taken in a limiting sense, and the scope of the present invention is defined only by the appended claims and equivalents thereof. The terms wafer or substrate used in the following description include any base semiconductor structure. Both are to be understood as including silicon-on-sapphire (SOS) technology, silicon-on-insulator (SOI) technology, thin film transistor (TFT) technology, doped and undoped semiconductors, epitaxial layers of a silicon supported by a base semiconductor structure, as well as other semiconductor structures well known to one skilled in the art. Furthermore, when reference is made to a wafer or substrate in the following description, previous process steps may have been utilized to form regions/junctions in the base semiconductor structure, and terms wafer or substrate include the underlying layers containing such regions/junctions.

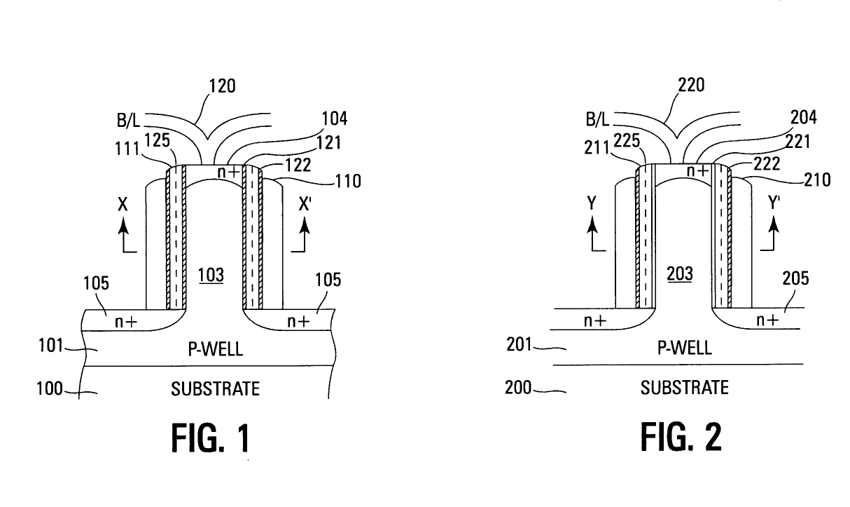

FIG. 1 illustrates a cross-sectional view of one embodiment of a surround gate transistor (SGT) PROM/INROM/flash memory cell of the present invention. Each cell is fabricated on a pillar in p-well 101 of a bulk silicon substrate 100. Even though the embodiments of the present invention are illustrated as being fabricated in a p-well of a silicon substrate with n+ diffusion areas, the present invention is not limited to this type of conductivity or even to a silicon substrate. Alternate embodiments can use an n-well with p-type diffusion areas that are fabricated in other types of semiconductor material.

For purposes of clarity, FIG. 1 illustrates only one of the memory cells that comprise an array of memory cells. It is well known in the art that a typical memory array may have millions or billions of these cells.

Each transistor is comprised of two diffusion regions 104, 105. The function (i.e., drain or source) of each region 104, 105 depends on the direction of operation of the transistor. These regions 104, 105, in one embodiment, are doped n+ regions in a p-type substrate 100. Alternate embodiments can use other types of doping.

In one embodiment, the top diffusion region 104 acts as a drain region 104 and is coupled to a bit line 120. As is well known in the art, the bit line 120 forms a column in an array of memory cells by coupling substantially similar memory cells. The manner in which the bit line is coupled to other memory cells determines whether the memory device is a NAND, NOR, or some other type of memory architecture.

Also in one embodiment, the lower diffusion region 105 acts as a source region 105 that is coupled to a source line for the array, as illustrated subsequently with reference to FIG. 7. In one embodiment, the source region 105 is an implanted layer at the planar surface of the p-well 101. This layer is self-aligned by the pillar mask during fabrication.

A vertical channel region exists between each pair of source/drain regions 104, 105 in the thin body silicon pillar 103. During operation of the transistor, a channel forms in the thin body pillar 103 between the drain 104 and the source 105.

The memory cell is additionally comprised of a vertical gate insulator stack that includes a tunnel insulator layer 121, a charge trapping layer 111, and a charge blocking layer 122. The surround gate/word line 110 is formed over the charge blocking layer 122. In one embodiment, the surround gate/word line 110 is comprised of a polysilicon material. The charge centroid 125 of a trapped charge is also illustrated in FIG. 1.

In one embodiment, the tunnel insulator 121 is comprised of LaAlO₃, oxidized nitride (e.g., oxygen-rich SiON), or very thin SiO₂ (i.e., EOT of 1-3 nm). The trapping layer 111 may be comprised of Ta₂O₅ having a dielectric constant of 26 (K=26), AlN having a K=10, TiO having a K=60, or a nitrogen-rich oxynitride (e.g., SiON) with a K=7. The charge blocking layer 122 may be comprised of LaAlO₃ (K=27.5), HfSiON (K=14), HfAlO (K=14 to 17), HfSiO (K=10) or Al₂O₃ (K=10). Alternate embodiments can use other materials for the gate insulator stack.

The insulator stack may be deposited using various fabrication techniques such as sputtering, atomic layer deposition (ALD), and/or chemical vapor deposition (CVD). Alternate embodiments may use other techniques or combinations of techniques. The effective oxide thickness (EOT) for the insulator stack of the PROM/INROM/flash memory, in one embodiment, is approximately in the range of 4 to 5 nm. Alternate embodiments may use other EOTs.

SONOS and nano-crystal types of non-volatile memory devices are typically referred to as discrete trap or embedded trap devices. The charge to be stored in the trap layer 111 tunnels through the tunnel insulator 121 and is confined there due to the charge blocking insulator layer 122. The tunneling may be accomplished by direct and Fowler-Nordheim tunneling during write operations while holes tunnel by direct tunneling during erase operations. In one embodiment, the program/erase voltage level for the SGT PROM/INROM/flash memory cells of the present invention is approximately 2.5V to 5V. Alternate embodiments may use other voltages.

Stored charge retention and erase speed sensitivity can depend on the tunneling distance (i.e., tunnel insulator thickness). For example, an increase in insulator thickness from an EOT of 1 nm to 3 nm of SiO₂ would result in a charge retention increase of approximately five orders of magnitude but also reducing the erase speed by nearly the same amount. This is due to the fact that both the back-tunneling electron current as well as the forward hole current are strongly dependent on tunneling distance that in turn depends on the insulator thickness, given the large band energy barriers of SiO₂ of 3.2 eV for electrons and 4.7 eV for holes (with reference to silicon), respectively.

The charge retention properties in the embodiments of the present invention, however, are improved by the use of a charge trapping layer 111 that has a deeper energy trap (e.g., Ta₂O₅ and SiON) than the nitride of a SONOS device. Additionally, the tunneling insulator 121 and the charge blocking layers 122 are chosen, as described above, to obtain higher electron and hole current for a given tunneling distance and, thus, improve programming and erasing speeds. These materials provide improved charge retention properties and write/erase speeds at lower EOT for the gate insulator stacks. The embodiment of FIG. 1 has threshold states that are non-volatile and stable for greater than ten years.

FIG. 2 illustrates a cross-sectional view of one embodiment of a surround gate transistor DRAM cell of the present invention. This device relies on a trade-off, by four or five magnitudes in one embodiment, between write/erase speeds and retention. By using the insulator materials as described previously and reducing the thickness of the tunnel insulator layer as compared to the PROM/NROM/flash memory cell embodiment of FIG. 1, the DRAM embodiment can have substantially longer retention (i.e., 10³ to 10⁴ seconds) as compared to a standard CMOS DRAM cell while attaining programming speeds on the order of nanoseconds.

The SGT, capacitor-less, DRAM of the present invention is comprised of two diffusion regions 204, 205. The function (i.e., drain or source) of each region 204, 205 depends on the direction of operation of the transistor. These regions 204, 205, in one embodiment, are doped n+ regions in a p-type substrate 200. Alternate embodiments can use other types of doping.

In one embodiment, the top diffusion region 204 acts as a drain region 204 and is coupled to a bit line 220. Also in one embodiment, the lower diffusion region 205 acts as a source region 205 that is coupled to a source line for the array, as illustrated subsequently with reference to FIG. 7. In one embodiment, the source region 205 is an implanted top layer at the planar surface of the p-well 201 and self-aligned by the pillar mask.

As in the PROM/INROM/flash memory cell embodiment of FIG. 1, the SGT DRAM cell is formed in the p-well 201 of a silicon substrate 200. However, also as described previously, the embodiments of the present invention can also be formed in an n-well of a p-type substrate.

A vertical channel region exists between each pair of source/drain regions 204, 205 in the thin body silicon pillar 203. During operation of the transistor, a channel forms in the thin body pillar 203 between the drain 204 and the source 205.

The memory cell is additionally comprised of a vertical gate insulator stack that includes a tunnel insulator layer 221, a charge trapping layer 211, and a charge blocking layer 222. The surround gate/word line 210 is formed over the charge blocking layer 222. In one embodiment, the surround gate/word line 210 is comprised of a polysilicon material. The charge trapping layer 211 and the charge blocking layer 222 can be made substantially similar or even identical to the embodiment of FIG. 1 to simplify the fabrication process.

FIG. 2 also illustrates the charge centroid 225 of the trapped charge in the charge trapping layer 211. In this embodiment, since the tunnel insulator 221 has a smaller EOT as compared to the embodiment of FIG. 1, the charge centroid 225 is closer to the thin body pillar 203. However, the charge centroid 225 of this embodiment is far enough from the body 203 to ensure data integrity such that the refresh frequency is reduced to approximately every 10³ to 10⁴ seconds. This results in lower operating power requirements than a typical DRAM. In one embodiment, the tunnel insulator layer 221 has an EOT of approximately 2.5 to 3 nm.

The embodiments of both FIGS. 1 and 2 rely on surround gate transistor architecture and customized insulator materials/thicknesses to provide scalability and immunity to short channel effects. This results in higher density integrated circuits and lower charge leakage for low power applications.

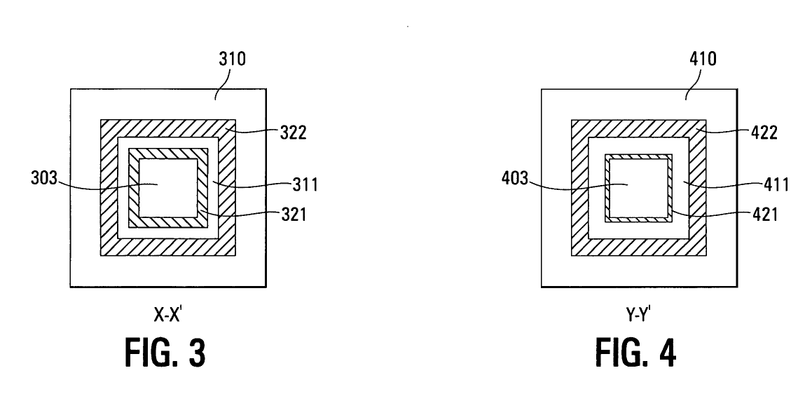

FIGS. 3 and 4 illustrate cross-sectional views along the x-x′ and y-y′ axes of FIGS. 1 and 2 respectively. These views show the details of the gate insulator stacks outwardly surrounding the silicon thin body pillars 303, 403. As described previously, the stacks are comprised of the tunnel insulators 321, 421, the charge trapping layers 311, 411, and the charge blocking insulators 322, 422. The surrounding polysilicon gates 310, 410 are also illustrated.

FIG. 4 shows that the tunnel insulator layer 421 for the SGT DRAM is thinner than the tunnel insulator layer 321 for the PROM/INROM/flash of FIG. 3. As described previously, this moves the charge centroid closer to the thin body silicon pillar 303, 403, thus reducing the time for program/erase operations.

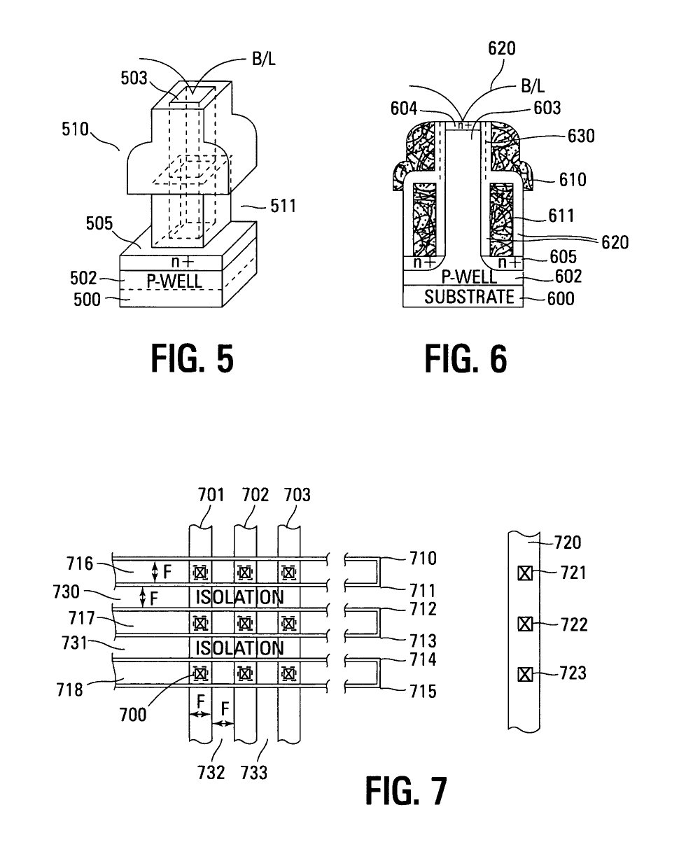

FIG. 5 illustrates a perspective view of an alternate embodiment of a SGT non-volatile memory (NVM) or NVM-DRAM of the present invention. This embodiment uses a split channel/overlapping split gate architecture that replaces the bottom DRAM capacitor element of a typical prior art DRAM cell by a fixed threshold element 511 with a single insulator. The top element 510 of the split channel device contains the charge trapping layer.

As in the above-described embodiments, the embodiment of FIG. 5 is based on a thin body silicon pillar 503 formed in a p-well or n-well 502, depending on the type of transistor, of a substrate 500. In one embodiment, the substrate is a silicon substrate 500. An implanted source diffusion layer 505 is formed on the planar surface of the p-well 502.

FIG. 6 shows a cross-sectional view of the split gate structure of the embodiment of FIG. 5. This view shows the substrate 600 with the well 602 on which is formed the thin body pillar 603. The diffusion layer 605 is formed over the substrate.

Around the thin body pillar 603 is formed the gate insulator stack 630 and single insulator material 620. The insulator 620 can include an oxide such as SiO₂, LaAlO₃, or some other insulator material. This insulator 620 surrounds the lower gate element 611 for the fixed element that, in one embodiment, is a polysilicon.

The gate stack 630 of the NVM or DRAM cell is fabricated in a substantially similar architecture around the thin body pillar 603 as the gate insulator stack of the embodiment of FIG. 1 (NVM) or FIG. 2 (DRAM). The upper, overlapping split gate 610 is formed over the gate insulator stack 630 and continuing the trapping layer overlapping the gate 611 of the fixed threshold element. A bit line 620 is coupled to the upper diffusion area 604 of the pillar that, in the illustrated embodiment, acts as a drain region 604.

For DRAM cell functionality, the embodiment of FIGS. 5 and 6 is capacitor-less in that the upper DRAM cell stores the data as a charge in the trapping layer as described previously with reference to FIG. 2. The lower, fixed threshold element, controls access to the upper, variable threshold DRAM cell through biasing of its control gate 611. Such an architecture improves the “0” state stability for the DRAM cell.

The NVM or NVM-DRAM cell of FIGS. 5 and 6 are comprised of a series integration of the fixed threshold element 511 and the bistable element 510 sharing a common source and drain. The threshold of the fixed threshold element 511, in one embodiment, is designed to be equal to or greater than the low threshold state of the bistable element 510 such that the low threshold state for the cell is defined by the threshold of the fixed threshold state. This provides minimum leakage of the cell during stand-by low state and yet is low enough to provide fast read-access speed during addressing of the memory cell. The high state of the cell is defined by the high threshold state of the bistable element 510. Both elements 510, 511 are active for cell operation.

FIG. 7 illustrates a top view of a memory array layout in accordance with the SGT memory cells of the present invention. This layout may be for a 4F² array design for either a surround gate, capacitor-less DRAM array, with an open bit line, or a one transistor NOR flash NVM array.

The array is comprised of the matrix of silicon pillars 700 with the self-aligned diffusion regions on top. In one embodiment, these are n+ drain regions. The active regions 716-718 that, in one embodiment, act as the source regions extend in the x-direction.

The vertical word lines 710-715 extend in the x-direction while the metal bit lines 701-703 extend substantially perpendicular in the y-direction. Isolation areas 730-733 are formed between the bit lines 701-703 and also between the word lines 710-715.

A common source line 720 is formed outside the memory array. The source line 720 has a plurality of buried contacts 721-723 to the array source regions. Because of the three dimensional layout, the buried common source line, as well as the word line gate, do not require contacts within the array. Additionally, with the self-aligned, top contacts for the bit lines, the array can achieve a higher density than prior art arrays.

The flash memory arrays of the present invention can be fabricated in any architecture including NAND, NOR, or AND. Alternate embodiments can be fabricated in other architectures.

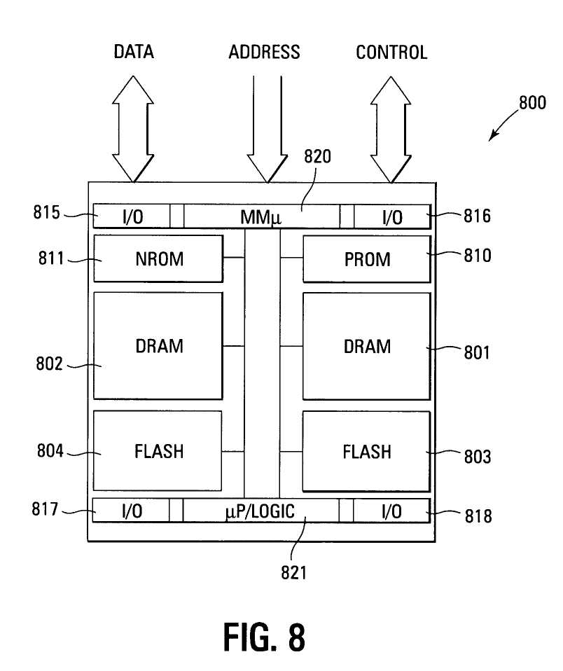

FIG. 8 illustrates a functional block diagram of a single chip controller/memory system device 800 that can incorporate the SGT NROM/PROM/flash/DRAM cells of the present invention. The fabrication technique of the above-described surround gate structures allows these different memory technologies to be fabricated on a single chip.

The embodiment of FIG. 8 is for purposes of illustration only. The SGT NROM/PROM/flash/DRAM cells of the present invention can be incorporated in any integrated circuit.

The memory system 800 is comprised of two SGT capacitor-less DRAM arrays 801, 802, two flash memory arrays 803, 804, a PROM array 810, and an NROM array 811. Each of these memory arrays is constructed using the memory cells described previously.

The system can further contain various input/output (I/O) ports 815-818 that can be coupled to outside signals such as data, address, and control buses. A memory management unit (MMU) 820 can be used to control access to each of the memory blocks 801-804, 810, 811 for both external access by another processor or by an internal microprocessor/control logic 821.

### CONCLUSION

In summary, the vertical, surround gate transistors of the present invention are nano-crystal based non-volatile memories that provide PROM/NROM/flash and DRAM functionality by changing the width of the tunnel insulator and customizing the materials of the insulator and trapping layers. The gate stack materials and fabrication scheme for a DRAM and a NVRAM array are substantially identical resulting in less costly fabrication. The architecture also provides lower power of operation and the vertical orientation is not only less sensitive to short channel effects, as compared to lateral devices, but vertical devices are more scalable.

Although specific embodiments have been illustrated and described herein, it will be appreciated by those of ordinary skill in the art that any arrangement that is calculated to achieve the same purpose may be substituted for the specific embodiments shown. Many adaptations of the invention will be apparent to those of ordinary skill in the art. Accordingly, this application is intended to cover any adaptations or variations of the invention. It is manifestly intended that this invention be limited only by the following claims and equivalents thereof.

What is claimed is:

1. A memory device comprising:
a pillar fabricated in a substrate;
a gate stack substantially surrounding the pillar wherein the gate stack is comprised of a tunnel insulator, a charge trap layer, and a charge blocking layer such that a charge retention property of the device is adjusted by a fabrication of an effective oxide thickness of the tunnel insulator; and
a gate substantially surrounding the gate stack.

2. The device of claim 1 wherein the pillar is located in a well of the substrate having a conductivity that is different than the conductivity of the remainder of the substrate.

3. The device of claim 1 wherein the substrate and pillar are comprised of silicon.

4. The device of claim 1 and further including a first diffusion region implanted at the top of the pillar and a second diffusion region implanted in the substrate substantially around the pillar.

5. The device of claim 4 wherein the first diffusion region acts a drain region and the second diffusion region acts as a source region.

6. The device of claim 1 wherein the tunnel insulator is fabricated to a first effective oxide thickness for a volatile random access memory and to a second effective oxide thickness, greater than the first thickness, for a non-volatile memory.

7. The device of claim 6 wherein the first effective oxide thickness is such that the volatile random access memory requires a periodic refresh operation.

8. The device of claim 6 wherein the second effective oxide thickness generates a flash memory device.

9. The device of claim 1 wherein the tunnel insulator is comprised of SiO₂ having an effective oxide thickness in a range of 1 to 3 nm.

10. A memory device comprising:
a pillar fabricated in a substrate, the pillar having a first diffusion region implanted at the top and the substrate having a second diffusion region implanted as a top layer in the substrate that substantially surrounds the bottom of the pillar;
a gate stack substantially surrounding the pillar wherein the gate stack is comprised of an oxidized nitride tunnel insulator, a charge trap layer, and a charge blocking layer such that a charge retention property of the device is determined during fabrication of an effective oxide thickness of the tunnel insulator; and
a gate substantially surrounding the gate stack.

11. The device of claim 10 wherein the pillar is fabricated in a p-well of the substrate and the first and second diffusion regions are n+ diffusions.

12. The device of claim 10 wherein the pillar is a thin body channel region in which a channel forms between the first and second diffusion regions during operation of the device.

13. The device of claim 10 wherein the tunnel insulator is comprised of oxygen-rich SiON.

14. The device of claim 10 wherein the charge trap layer is comprised of one of: Ta₂O₅, AIN, TiO₂, or oxygen-rich SiON.

15. The device of claim 10 wherein the charge blocking layer is comprised of one of:
LaAlO₃, HfSiON, HfAlO, HfSiO, or Al₂O₃.

16. The device of claim 10 wherein the effective oxide thickness of the tunnel insulator is substantially in a range of 2.5 to 3 nm for a DRAM memory device and the tunnel insulator is substantially in an effective oxide thickness range of 4 to 5 nm for a flash memory device.

17. A memory device comprising:
a pillar fabricated in a substrate, the pillar having a first diffusion region implanted at the top and the substrate having a second diffusion region implanted as a top layer in the substrate that substantially surrounds the bottom of the pillar;
a gate stack substantially surrounding the pillar wherein the gate stack is comprised of a LaAlO₃ tunnel insulator, a charge trap layer, and a charge blocking layer such that a charge retention property of the device is determined during fabrication of an effective oxide thickness of the tunnel insulator; and
a polysilicon gate substantially surrounding the gate stack.

18. The device of claim 17 wherein the memory device has characteristics of one of a PROM cell or a flash memory cell when the tunnel insulator effective oxide thickness is substantially in a range of 2.5 to 3 nm and the memory device has characteristics of a DRAM when the tunnel insulator effective oxide thickness is substantially in a range of 4 to 5 nm.

19. A capacitor-less DRAM cell comprising:
a thin body silicon pillar formed on a silicon substrate, the pillar having a first diffusion region implanted at the top and the substrate having a second diffusion region implanted in the surface surrounding the pillar;
a fixed threshold element comprising a first surround gate surrounded by an insulator material, the first surround gate and the insulator material surrounding the pillar; and
a variable threshold element comprising a second surround gate formed around a gate stack having a tunnel insulator, a charge trap layer, and a charge blocking layer, both the second surround gate and the gate stack surrounding the pillar above the fixed threshold element, a charge retention characteristic of the variable threshold element altered in response to a fabricated thickness of the tunnel insulator.

20. The cell of claim 19 wherein the insulator material is one of SiO₂ or LaAlO₃.

21. The cell of claim 19 wherein the pillar is formed in a well having a conductivity that is different than the conductivity of the remainder of the substrate.

22. The cell of claim 21 wherein the well is a p-well and the first and second diffusion regions are n+ regions.

23. The cell of claim 19 wherein the pillar further comprises a split channel region between the first and second diffusion regions, a first channel adapted to form in a lower portion of the channel region in response to biasing of the first surround gate and a second channel adapted to form in an upper portion of the channel region in response to biasing of the second surround gate.

24. A memory array comprising:
a plurality of pillars formed in a substrate, each pillar having an implanted diffusion region at the top and the substrate having a second implanted diffusion region surrounding each pillar;
a plurality of gate stacks, each gate stack surrounding each pillar and comprising a tunnel insulator, a charge trap layer, and a charge blocking layer such that a charge retention property of each charge trap layer varies with a fabricated thickness of the tunnel insulator; and
a surrounding gate surrounding the gate stack.

25. The array of claim 24 and further including a common source line that is coupled to the second implanted diffusion regions.

26. The array of claim 24 wherein a first set of the plurality of pillars comprise DRAM devices and a second set comprise non-volatile memory devices.

27. The array of claim 24 wherein a first set of the plurality of gate stacks comprises gate stacks having a first charge retention property and a second set of the memory array comprises gate stacks having a second charge retention property that is different from the first charge retention property.

28. The array of claim 24 wherein the tunnel insulator is comprised of one of: an oxidized nitride, LaAlO₃, or SiO₂ and the charge trap layer is comprised of one of:
Ta₂O₅, AIN, TiO₂, or nitrogen-rich oxynitride, and the charge blocking layer is comprised of one of: LaAlO₃, HfSiON, HfAlO, HfSiO, or A1₂O₃.

29. A memory array comprising:
a plurality of pillars formed in a substrate, each pillar having an implanted diffusion region at the top and the substrate having an implanted diffusion region surrounding each pillar;
a plurality of gate stacks, each gate stack surrounding each pillar and comprising a tunnel insulator, a charge trap layer, and a charge blocking layer such that a charge retention property of each charge trap layer varies with a fabricated thickness of the tunnel insulator and composition of each layer of the gate stack; and
a surrounding gate surrounding the gate stack.

30. A memory system on a substrate, the system comprising:
a first set of memory cells comprising:
a plurality of pillars on the substrate, each pillar having an implanted diffusion region at the top and the substrate having an implanted diffusion region surrounding each pillar;
a plurality of gate stacks, each gate stack surrounding each pillar and comprising a tunnel insulator having a first effective oxide thickness, a charge trapping layer, and a charge blocking layer; and
a gate surrounding the gate stack; and
a second set of memory cells comprising:
a plurality of pillars on the substrate, each pillar having an implanted diffusion region at the top and the substrate having an implanted diffusion region surrounding each pillar;
a plurality of gate stacks, each gate stack surrounding each pillar and comprising a tunnel insulator having a second effective oxide thickness, a charge trapping layer, and a charge blocking layer, the second effective oxide thickness being greater than the first effective oxide thickness; and
a gate surrounding the gate stack.

31. The system of claim 30 wherein the first set of memory cell are non-volatile memory cells and the second set of memory cells are DRAM memory cells.

32. The system of claim 31 wherein the non-volatile memory cells are at least one of flash, NROM, or PROM cells.

33. The system of claim 30 and further including a memory management unit coupled to the first and second set of memory cells, at least one input/output port coupled to the first and second set of memory cells, and control logic coupled to the first and second set of memory cells.

34. A plurality of integrated vertical memory cells on a substrate comprising:
a plurality of sets of pillars on the substrate;
a plurality of gate stacks, each gate stack surrounding a pillar and having substantially similar charge retention properties with other gate stacks within its set of pillars but different charge retention properties from gate stacks of other sets of pillars such that a first set of memory cells are non-volatile and a second set of memory cells are volatile; and
a plurality of gates, each gate surrounding a gate stack.

35. The cells of claim 34 wherein the charge retention properties are adjusted in response to fabrication materials of the gate stacks.

36. The cells of claim 34 wherein the volatile memory cells are capacitor—less DRAM cells that are comprised of gate stacks having insulators comprising one of SiO₂ or LaAlO₃.

37. The cells of claim 36 wherein the DRAM cells are split gate cells having a fixed threshold element and a variable threshold element.

38. The cells of claim 34 wherein the gate stacks are each comprised of a tunnel insulator, a charge trap layer, and a charge blocking layer such that the charge retention properties of each gate stack is set during fabrication by an effective oxide thickness of the tunnel insulator.

39. A method for fabricating a surround gate memory cell array, the method comprising:
forming a plurality of pillars on a substrate;
implanting a first diffusion region in the tops of each pillar and a second diffusion region in the substrate surrounding the plurality of pillars;
forming a gate stack surrounding each pillar, the gate stack comprising a tunnel insulator, a charge trap layer, and a charge blocking layer, wherein forming the tunnel insulator comprises increasing an effective oxide thickness to increase a charge retention property of each memory cell; and
forming a gate surrounding the gate stack.
